(19) United States
(12) Patent Application Publication
(10) Pub. No.: US 2024/0204064 A1
(43) Pub. Date: Jun. 20, 2024

(54) DIELECTRIC BARRIER FOR BACKSIDE INTERCONNECT SEPARATION

(71) Applicant: Intel Corporation, Santa Clara, CA (US)

(72) Inventors: Guillaume Bouche, Portland, OR (US); Bilal Chehab, Portland, OR (US); Lars Liebmann, Mechanicville, NY (US); Quan Shi, Portland, OR (US)

(73) Assignee: Intel Corporation, Santa Clara, CA (US)

(21) Appl. No.: 18/084,844

(22) Filed: Dec. 20, 2022

(51) Int. Cl. H01L 29/417; H01L 21/8238; H01L 27/092; H01L 29/06; H01L 29/40; H01L 29/423; H01L 29/66; H01L 29/775

(52) U.S. Cl. CPC H01L 29/41733; H01L 21/823807; H01L 21/823821; H01L 21/823871; H01L 27/092; H01L 29/0673; H01L 29/401; H01L 29/42392; H01L 29/66439; H01L 29/775

(57) ABSTRACT

Techniques are provided herein to form semiconductor devices having a dielectric wall or spine between two devices that extends between source or drain regions of the two devices and separates backside contacts to the source or drain regions. A first semiconductor device includes a first semiconductor region extending from a first source or drain region and a second adjacent semiconductor device includes a second semiconductor region extending from a second source or drain region adjacent to the first source or drain region. A dielectric wall extends between the first source or drain region and the second source or drain region. A first backside contact touches the underside of the first source or drain region and a second backside contact touches the underside of the second source or drain region. The dielectric wall further extends down between the first conductive contact and the second conductive contact.

### FIELD OF THE DISCLOSURE

The present disclosure relates to integrated circuits, and more particularly, to transistor connections that use backside contacts.

### BACKGROUND

As integrated circuits continue to scale downward in size, a number of challenges arise. For instance, reducing the size of memory and logic cells is becoming increasingly more difficult. One possible solution includes the use of a backside interconnect structure. For example, backside contacts may be used to reduce routing congestion within a frontside interconnect structure. However, there remain a number of non-trivial challenges with respect to forming backside contacts.

### BRIEF DESCRIPTION OF THE DRAWINGS

FIGS. 1A and 1B are cross-sectional views of an integrated circuit structure that includes a dielectric wall separating backside conductive contacts and traces, in accordance with an embodiment of the present disclosure.

FIG. 1C is a plan view of the integrated circuit structure from FIGS. 1A and 1i, in accordance with an embodiment of the present disclosure.

FIGS. 2A and 2B are cross-sectional views that illustrate one stage in an example process for forming an integrated circuit configured with a dielectric wall separating backside conductive contacts and traces, in accordance with an embodiment of the present disclosure.

FIGS. 3A and 3B are cross-sectional views that illustrate another stage in the example process for forming an integrated circuit configured with a dielectric wall separating backside conductive contacts and traces, in accordance with an embodiment of the present disclosure.

FIGS. 4A and 4B are cross-sectional views that illustrate another stage in the example process for forming an integrated circuit configured with a dielectric wall separating backside conductive contacts and traces, in accordance with an embodiment of the present disclosure.

FIGS. 5A and 5B are cross-sectional views that illustrate another stage in the example process for forming an integrated circuit configured with a dielectric wall separating backside conductive contacts and traces, in accordance with an embodiment of the present disclosure.

FIGS. 6A and 6B are cross-sectional views that illustrate another stage in the example process for forming an integrated circuit configured with a dielectric wall separating backside conductive contacts and traces, in accordance with an embodiment of the present disclosure.

FIGS. 7A and 7B are cross-sectional views that illustrate another stage in the example process for forming an integrated circuit configured with a dielectric wall separating backside conductive contacts and traces, in accordance with an embodiment of the present disclosure.

FIGS. 8A and 8B are cross-sectional views that illustrate another stage in the example process for forming an integrated circuit configured with a dielectric wall separating backside conductive contacts and traces, in accordance with an embodiment of the present disclosure.

FIGS. 9A and 9B are cross-sectional views that illustrate another stage in the example process for forming an integrated circuit configured with a dielectric wall separating backside conductive contacts and traces, in accordance with an embodiment of the present disclosure.

FIGS. 10A and 10B are cross-sectional views that illustrate another stage in the example process for forming an integrated circuit configured with a dielectric wall separating backside conductive contacts and traces, in accordance with an embodiment of the present disclosure.

FIGS. 11A and 11B are cross-sectional views that illustrate another stage in the example process for forming an integrated circuit configured with a dielectric wall separating backside conductive contacts and traces, in accordance with an embodiment of the present disclosure.

FIGS. 12A and 12B are cross-sectional views that illustrate another stage in the example process for forming an integrated circuit configured with a dielectric wall separating backside conductive contacts and traces, in accordance with an embodiment of the present disclosure.

FIG. 13 illustrates a cross-section view of a chip package containing one or more semiconductor dies, in accordance with some embodiments of the present disclosure.

FIG. 14 is a flowchart of a fabrication process for semiconductor device having a dielectric wall separating backside conductive contacts and traces, in accordance with an embodiment of the present disclosure.

FIG. 15 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form semiconductor devices having a dielectric wall separating backside conductors. In an example, a dielectric wall or spine is formed that extends between source or drain regions of two devices and separates backside contacts to the source or drain regions. The techniques can be used in any number of integrated circuit applications and are particularly useful with respect to logic and memory cells, such as those cells that use finFETs, forksheet transistors, or gate-all-around transistors. In an example, a first semiconductor device includes a first semiconductor region, such as one or more first nanoribbons or nanosheets, extending from a first source or drain region, and a second adjacent semiconductor device includes a second semiconductor region, such as one or more second nanoribbons or nanosheets, extending from a second source or drain region adjacent to the first source or drain region. A dielectric wall extends between the first semiconductor region and the second semiconductor region and also between the first source or drain region and the second source or drain region. A first backside contact touches the underside of the first source or drain region, and a second backside contact touches the underside of the second source or drain region. According to an embodiment, the dielectric wall further extends down between the first conductive contact and the second conductive contact. The dielectric wall may also extend further to separate conductive traces coupled to the first conductive contact and the second conductive contact. By separating backside conductive structures with the dielectric wall, alignment errors that could lead to shorting between patterned traces are reduced or avoided entirely. Numerous variations and embodiments will be apparent in light of this disclosure.

### General Overview

As previously noted above, there remain a number of non-trivial challenges with respect to forming backside contacts to semiconductor devices. Backside contacts may be formed to directly contact the underside of source or drain regions by replacing a sacrificial plug with conductive material after removing the substrate from the backside of the structure. While this process may yield self-aligned backside contacts, patterning additional conductive layers (e.g., conductive traces) to separately contact the various conductive contacts is more challenging. The contacts are often very close together which results in very tight alignment tolerances that may be within the edge placement error (EPE) of standard lithography equipment. If a conductive trace is misaligned, it may cause an undesirable short between two or more conductive contacts.

Thus, and in accordance with an embodiment of the present disclosure, techniques are provided herein to form a dielectric wall that extends between semiconductor devices and also separates backside conductive structures from one another to reduce or eliminate shorting between the backside conductive structures. The dielectric wall may be similar to a dielectric spine used in a forksheet arrangement with semiconductor regions of two different devices extending along opposite sides of the dielectric wall. According to some embodiments, a buried sacrificial layer within the substrate is used as a placeholder while the dielectric wall is formed (during frontside processing) to extend down between adjacent semiconductor fins and also through at least a full thickness of the buried sacrificial layer. During backside processing, bulk substrate can be removed along with the buried sacrificial layer, thus exposing the dielectric wall. The dielectric wall remains extending away from the backside surface and acting as a physical barrier between conductive layers subsequently formed on the backside surface, for routing signal or power to one or more backside contacts. The dielectric wall may be formed, for instance, from any suitable dielectric material that exhibits a high etch selectivity to the substrate material and the material of the buried sacrificial layer. In some examples, the dielectric wall includes any of silicon nitride (Si₃N₄), titanium dioxide (TiO₂), aluminum nitride (AlN), or aluminum oxide (Al₂O₃).

According to an embodiment, an integrated circuit includes a first semiconductor device having a first semiconductor region extending in a first direction from a first source or drain region, and a first gate structure extending in a second direction over the first semiconductor region. The integrated circuit further includes a second semiconductor device having a second semiconductor region extending in the first direction from a second source or drain region, and a second gate structure extending in the second direction over the second semiconductor region. The second source or drain region is adjacent to the first source or drain region along the second direction. The integrated circuit further includes a first conductive contact on an underside of the first source or drain region, a second conductive contact on an underside of the second source or drain region, and a dielectric wall extending in the first direction between and contacting both the first semiconductor region and the second semiconductor region and extending between both the first source or drain region and the second source or drain region. The dielectric wall further extends in a third direction along at least an entire thickness of the first conductive contact and the second conductive contact. The dielectric wall may further extend in the third direction between a first conductive layer on the first conductive contact and a second conductive layer on the second conductive contact.

According to another embodiment, an integrated circuit includes a first semiconductor device having a first semiconductor region extending in a first direction from a first source or drain region, and a first gate structure extending in a second direction over the first semiconductor region. The integrated circuit further includes a second semiconductor device having a second semiconductor region extending in the first direction from a second source or drain region, and a second gate structure extending in the second direction over the second semiconductor region. The second source or drain region is adjacent to the first source or drain region along the second direction. The integrated circuit further includes a dielectric layer beneath the first source or drain region and the second source or drain region, a first conductive contact extending through an entire thickness of the dielectric layer and contacting an underside of the first source or drain region, a second conductive contact extending through the entire thickness of the dielectric layer and contacting an underside of the second source or drain region, and a dielectric wall extending in the first direction between the first source or drain region and the second source or drain region. The dielectric wall further extends in a third direction between the first conductive contact and the second conductive contact.

According to another embodiment, a method of forming an integrated circuit includes forming a sacrificial layer over a substrate; forming a sublayer on the sacrificial layer and one or more semiconductor layers on the sublayer; forming a fin from the one or more semiconductor layers and the sublayer extending above the sacrificial layer; forming a dielectric layer adjacent to the sublayer and on the sacrificial layer; forming a dielectric wall through an entire thickness of the fin and through an entire thickness of the sacrificial layer; removing portions of the one or more semiconductor layers and the sublayer on either side of the dielectric wall, thus exposing the underlying sacrificial layer; forming a first sacrificial plug on an exposed portion of the sacrificial layer and a second sacrificial plug on another exposed portion of the sacrificial layer, wherein the dielectric wall is between the first sacrificial plug and the second sacrificial plug; forming source or drain regions above the first and second sacrificial plugs; removing the substate to expose a backside of the sacrificial layer; removing the sacrificial layer; replacing the first and second sacrificial plugs with first and second conductive plugs, respectively; and forming a first conductive layer on the first conductive plug and a second conductive layer on the second conductive plug, wherein the dielectric wall separates the first conductive layer from the second conductive layer.

The techniques can be used with any type of non-planar transistors, including finFETs (sometimes called double-gate transistors, or tri-gate transistors), forksheet transistors, or and nanoribbon transistors (sometimes called gate-all-around transistors), to name a few examples. The source and drain regions can be, for example, epitaxial regions that are deposited during an etch-and-replace source/drain forming process. The dopant-type in the source and drain regions will depend on the polarity of the corresponding transistor. The source and drain regions may be any epitaxial diffusion region. The gate structure can be implemented with a gate-first process or a gate-last process (sometimes called a remove metal gate, or RMG, process). Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate a dielectric wall, like the spine of forksheet transistors, that extends between backside conductive contacts and/or backside conductive layers. The backside conductive contacts and/or backside conductive layers may be in direct contact with opposite sides of the dielectric wall. Numerous configurations and variations will be apparent in light of this disclosure.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element (s) or feature (s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the materials has an element that is not in the other material.

### Architecture

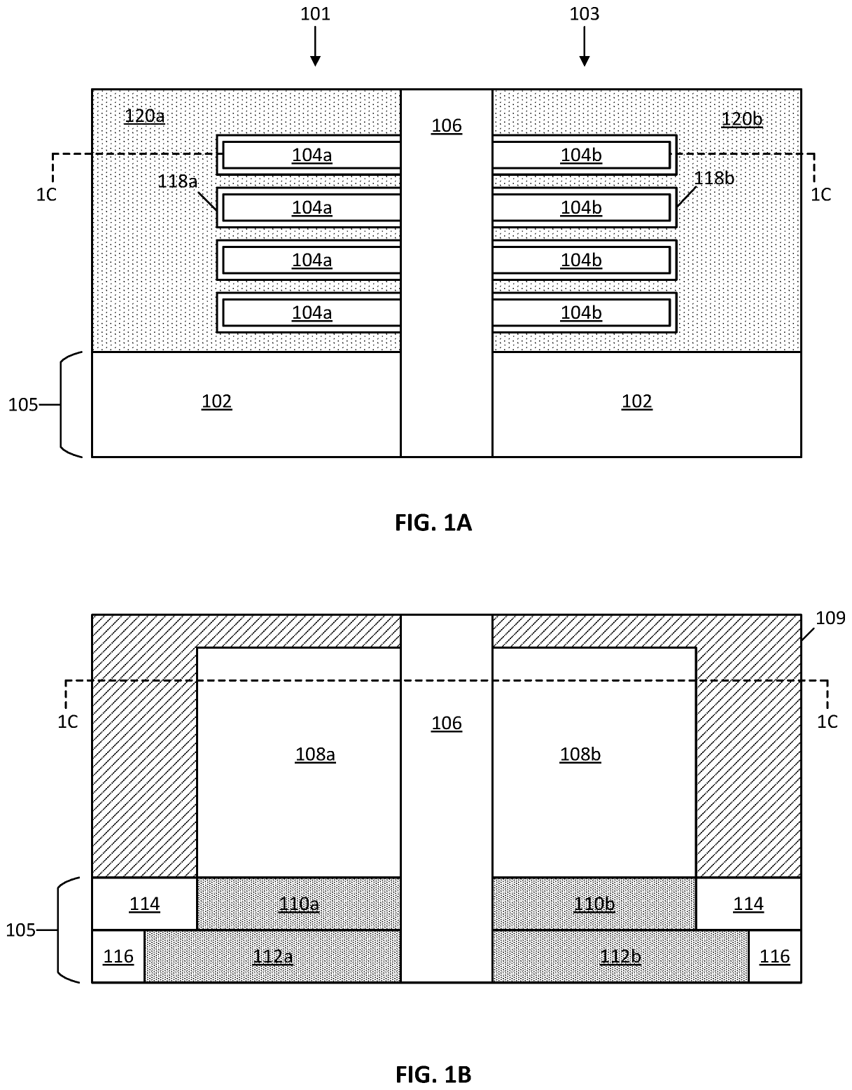

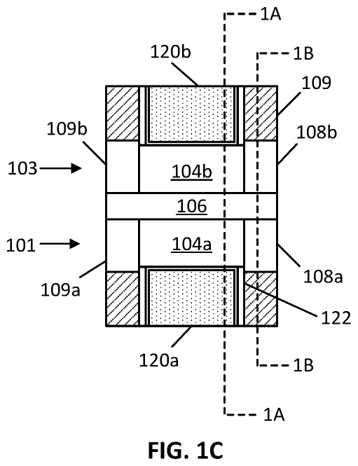

FIG. 1A is a cross-sectional view taken across the gate trench of two example semiconductor devices, a first semiconductor device 101 and a second semiconductor device 103, according to an embodiment of the present disclosure. FIG. 1B is another cross-sectional view taken across the source/drain or diffusion region (and contact trench) adjacent to the gate trench either into or out of the page of FIG. 1A. FIG. 1C is a top-down cross-section view of the adjacent semiconductor devices 101 and 103 taken across the dashed line 1C-1C depicted in both FIG. 1A and FIG. 1B. FIG. 1A illustrates the cross-section taken across the dashed line 1A-1A depicted in FIG. 1C, and FIG. 1B illustrates the cross-section taken across the dashed line 1B-1B depicted in FIG. 1C.

Each of semiconductor devices 101 and 103 may be, for example, non-planar metal oxide semiconductor (MOS) transistors, such as tri-gate (e.g., finFET or forksheet) or gate-all-around (GAA) transistors, although other transistor topologies and types could also benefit from the techniques provided herein. The illustrated example embodiments use the forksheet structure. The various illustrated semiconductor devices represent a portion of an integrated circuit that may contain any number of similar semiconductor devices.

As can be seen, semiconductor devices 101 and 103 are formed over a backside interconnect structure 105. Any number of semiconductor devices can be formed over backside interconnect structure 105, but two are illustrated here as an example. According to some embodiments, a semiconductor substrate is removed from the backside and replaced with backside interconnect structure 105. Backside interconnect structure 105 may include any number of interconnect layers that include a dielectric layer and any number of conductive structures, such as conductive vias or conductive layers. An etch stop layer (e.g., a relatively thin layer of silicon nitride about 3-10 nm thick) may separate one interconnect layer from the next. In the example cross-section of FIG. 1A, backside interconnect structure 105 includes a dielectric layer 102 beneath the gate structures of semiconductor devices 101 and 103. In some embodiments, dielectric layer 102 represents any number of dielectric layers. Other layer configurations may be used as well beneath the gate structures of semiconductor devices 101 and 103. The portion of backside interconnect structure 105 beneath the source or drain regions, as illustrated in FIG. 1B, includes a different arrangement of conductive features and dielectric layers, as will be discussed in turn.

Each of semiconductor devices 101 and 103 includes one or more nanosheets 104a and 104b, respectively, that extend parallel to one another along a direction between corresponding source or drain regions, as seen more clearly in FIG. 1C (e.g., a first direction into and out of the page in the cross-section view of FIG. 1A). Specifically, nanosheets 104a of first semiconductor device 101 extend between source or drain region 108a and source or drain region 109a and nanosheets 104b of second semiconductor device 103 extend between source or drain region 108b and source or drain region 109b.

Nanosheets 104a/104b are one example of semiconductor regions or semiconductor bodies that extend between the source or drain regions. The term nanosheet may also encompass other similar shapes such as nanowires or nanoribbons. The semiconductor material of nanosheets 104a/104b may be formed from the original substrate that was removed to form backside interconnect structure 105. In some embodiments, semiconductor devices 101 and 103 may each include semiconductor regions in the shape of fins that can be, for example, native to the substrate (formed from the substrate itself), such as silicon fins etched from a bulk silicon substrate. Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, non-native fins can be formed in a so-called aspect ratio trapping based process, where native fins are etched away so as to leave fin-shaped trenches which can then be filled with an alternative semiconductor material (e.g., group IV or III-V material). In still other embodiments, the fins include alternating layers of material (e.g., alternating layers of silicon and SiGe) that facilitate forming of the illustrated nanosheets 104a/104b during a gate forming process where one type of the alternating layers is selectively etched away so as to liberate the other type of alternating layers within the channel region, so that a forksheet gate-forming process can then be carried out. Again, the alternating layers can be blanket deposited and then etched into fins or deposited into fin-shaped trenches. According to some embodiments, nanosheets 104a/104b (or other semiconductor bodies) extend between corresponding source or drain regions in the first direction to provide an active region (sometimes called channel region) for a transistor (e.g., the semiconductor region beneath the gate).

According to some embodiments, the source or drain regions are epitaxial regions that are provided using an etch-and-replace process. Any semiconductor materials suitable for source and drain regions can be used (e.g., group IV and group III-V semiconductor materials). The composition and doping of the source or drain regions may be the same or different, depending on the polarity of the transistors. In an example, for instance, one transistor is a p-type MOS (PMOS) transistor, and the other transistor is an n-type MOS (NMOS) transistor. Any number of source or drain configurations and materials can be used. According to some embodiments, a dielectric fill 109 is provided around and/or over portions of source or drain regions 108a/108b along the source/drain trench after epitaxial formation of source or drain regions 108a/108b is complete. Dielectric fill 109 may be any suitable dielectric material, such as silicon dioxide or silicon oxynitride.

According to some embodiments, a dielectric wall 106 separates nanosheets 104a from nanosheets 104b (or any other semiconductor bodies from each other). Nanosheets 104a may directly contact one side of dielectric wall 106 while nanosheets 104b directly contact the opposite side of dielectric wall 106. According to some embodiments, dielectric wall 106 includes any suitable dielectric material. For example, dielectric wall 106 may include any of silicon nitride (Si₃N₄), titanium dioxide (TiO₂), aluminum nitride (AlN), or aluminum oxide (Al₂O₃). Dielectric wall 106 may have a width extending between nanosheets 104a and nanosheets 104b of 5 nm-30 nm.

According to some embodiments, dielectric wall 106 also extends in the first direction between source or drain region 108a and source or drain region 108b as shown in FIG. 1B. In this example, source or drain region 108a directly contacts one side of dielectric wall 106 while source or drain region 108b directly contacts the opposite side of dielectric wall 106. As further shown in this example, dielectric wall 106 also extends beneath the source or drain regions such that it separates a first backside contact 110a from a second backside contact 110b. First backside contact 110a may contact an underside of source or drain region 108a while second backside contact 110b may contact an underside of source or drain region 108b. Each of first backside contact 110a and second backside contact 110b may be part of a local interconnect or an interconnect layer of backside interconnect structure 105 that also includes backside dielectric layer 114 adjacent to first backside contact 110a and second backside contact 110b. According to some embodiments, first backside contact 110a and second backside contact 110b may include any suitable conductive material, such as tungsten, cobalt, ruthenium, copper, titanium, molybdenum, or any alloys thereof. In some cases, the first backside contact 110a and the second backside contact 110b each includes a liner and/or barrier layer and a fill metal. Other examples may include any number of layers and materials (e.g., silicide layers at semiconductor-metal interface, adhesion layers, resistance-reducing layers, to name a few examples). Backside dielectric layer 114 may include any suitable dielectric material such as silicon dioxide or silicon oxynitride. According to some embodiments, dielectric wall 106 further extends into another interconnect layer of backside interconnect structure 105, such that dielectric wall 106 separates a first conductive layer 112a from a second conductive layer 112b. Each of first conductive layer 112a and second conductive layer 112b may be part of another interconnect layer of backside interconnect structure 105 that also includes another backside dielectric layer 116 adjacent to first conductive layer 112a and second conductive layer 112b. According to some embodiments, first conductive layer 112a and second conductive layer 112b may include any suitable conductive material, such as tungsten, cobalt, ruthenium, copper, titanium, molybdenum, or any alloys thereof. Backside dielectric layer 116 may include any suitable dielectric material such as silicon dioxide or silicon oxynitride. First and second conductive layers 112a and 112b may be, for example, vias or conductive traces carrying signal or rail power to corresponding conductive contacts 110a and 110b. In some such cases, a relatively thin etch stop layer may be between dielectric layers 114 and 116. In one such case, each of first conductive layer 112a and second conductive layer 112b extend through that etch stop layer to contact first backside contact 110a and second backside contact 110b, respectively. In one example, one or both of first conductive layer 112a and second conductive layer 112b is/are a dual damascene structure that includes a via portion and a metal line portion. Any number of interconnect schemes can be used.

According to some embodiments, backside contacts 110a and 110b directly contact opposite sides of dielectric wall 106, and conductive layers 112a and 112b directly contact opposite sides of dielectric wall 106. By using dielectric wall 106 to provide physical separation between both backside contacts 110a and 110b and between conductive layers 112a and 112b, the risk of shorting between the backside contacts is greatly reduced or eliminated.

According to some embodiments, a first gate structure extends over and around nanosheets 104a of semiconductor device 101 along a second direction across the page while a second gate structure extends over and around nanosheets 104b of semiconductor device 103 along the second direction. Each gate structure includes a respective gate dielectric 118a/118b and a gate layer (or gate electrode) 120a/120b. Gate dielectric 118a/118b represents any number of dielectric layers present between nanosheets 104a/104b and gate electrode 120a/120b. Gate dielectric 118a/118b may also be present on the surfaces of other structures within the gate trench. Gate dielectric 118a/118b may include any suitable gate dielectric material(s). In some embodiments, gate dielectric 118a/118b includes a layer of native oxide material (e.g., silicon dioxide) on the nanosheets or other semiconductor regions making up the channel region of the devices, and a layer of high-k dielectric material (e.g., hafnium oxide) on the native oxide.

Gate electrode 120a/120b may represent any number of conductive layers, such as any metal, metal alloy, or doped polysilicon layers. In some embodiments, gate electrode 120a/120b includes one or more workfunction metals around nanosheets 104a/104b. In some embodiments, one of semiconductor devices 101 and 103 is a p-channel device that includes a workfunction metal having titanium around its nanosheets and the other semiconductor device is an n-channel device that includes a workfunction metal having tungsten around its nanosheets. Gate electrode 120a/120b may also include a fill metal or other conductive material around or otherwise on the workfunction metals to provide the whole gate electrode structure. According to some embodiments, the gate structures (or more specifically gate electrodes 120a/120b) may include a dielectric cap on a top surface of gate electrodes 120a/120b. The dielectric cap may include any suitable dielectric material, such as silicon nitride.

FIG. 1C illustrates a plan view of the integrated circuit showing how dielectric wall 106 cuts across both the gate trench and the source/drain trench to isolate first semiconductor device 101 from second semiconductor device 103. According to some embodiments, spacer structures 122 extend along the sides of the gate trench and isolate the gate trench from the source/drain trench (including epi regions and their respective contacts). Spacer structures 122 may include any suitable dielectric material, such as silicon nitride. The nanosheets 104a/104b (or other channel bodies) extend through spacer structures 122 to contact respective source or drain regions.

### Fabrication Methodology

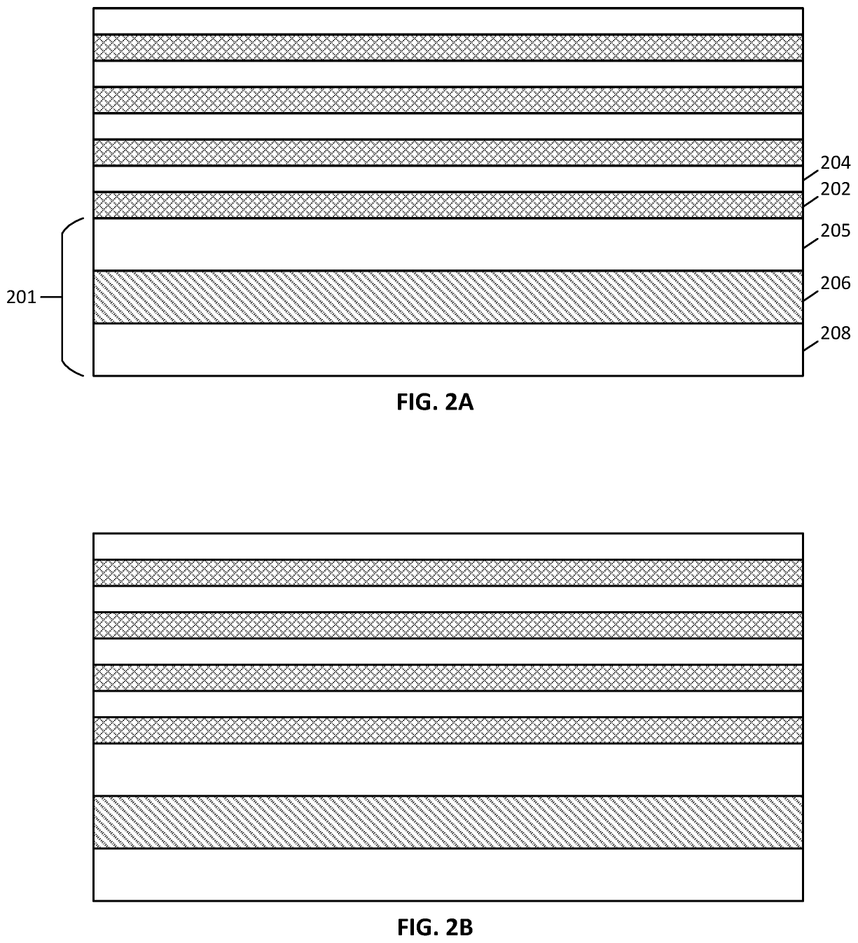

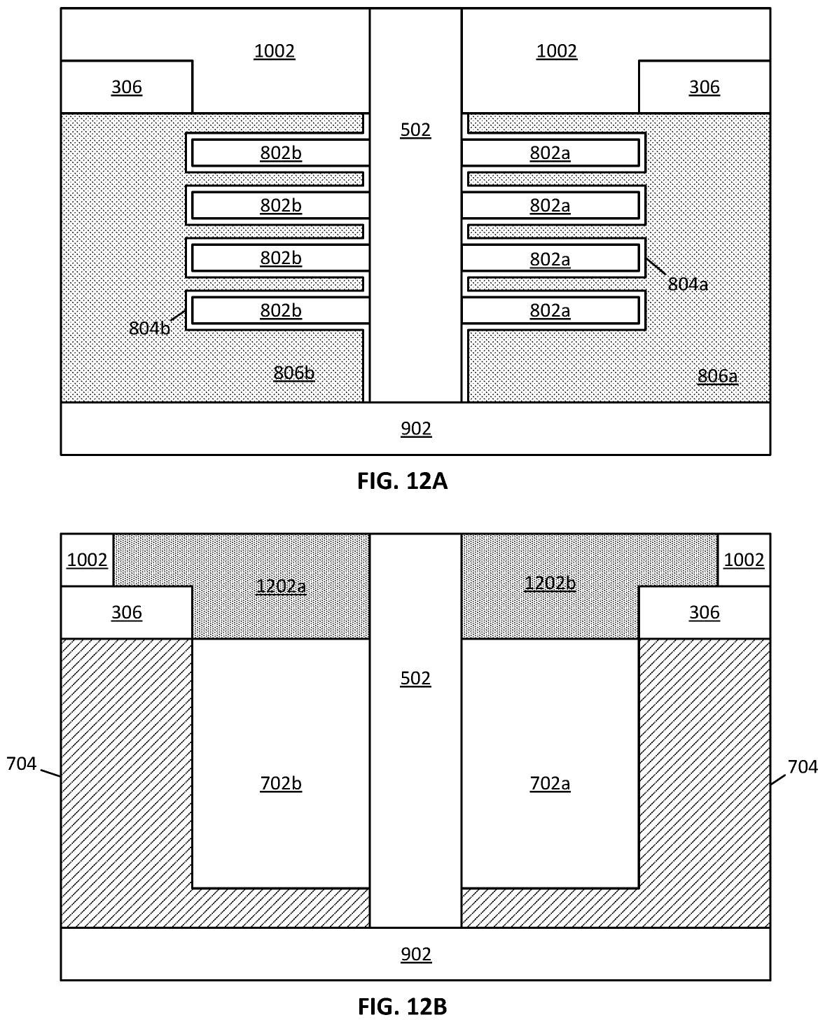

FIGS. 2A-12A and 2B-12B are cross-sectional views that collectively illustrate an example process for forming an integrated circuit configured with a dielectric wall between backside conductive structures, in accordance with an embodiment of the present disclosure. FIGS. 2A-12A represent cross-sectional views taken across a gate trench of the integrated circuit, while FIGS. 2B-12B represent cross-sectional views taken across the source/drain trench adjacent to the gate trench along the same direction. Each figure shows an example structure that results from the process flow up to that point in time, so the depicted structure evolves as the process flow continues, culminating in the structure shown in FIGS. 12A and 12B, which is similar to the structure shown in FIGS. 1A and 1B. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but the present disclosure is not intended to be limited to any specific such materials or parameters, as will be appreciated. Figures sharing the same number (e.g., FIGS. 2A and 2B) illustrate different views of the structure at the same point in time during the process flow.

FIGS. 2A and 2B illustrate parallel cross-sectional views taken through a stack of alternating semiconductor layers on a semiconductor substrate 201. FIG. 2A is taken across a portion of the stack that will eventually become a gate trench while FIG. 2B is taken across a portion of the stack that will eventually become a source/drain trench adjacent and parallel to the gate trench. Alternating material layers may be deposited over substrate 201 including sacrificial layers 202 alternating with semiconductor layers 204. The alternating layers are used to form forksheet or GAA transistor structures. Any number of alternating semiconductor layers 204 and sacrificial layers 202 may be deposited over substrate 201.

According to some embodiments, substrate 201 includes a sublayer 205 directly beneath the alternating layer stack, a buried sacrificial layer 206, and a bulk region 208. Buried sacrificial layer 206 is disposed between sublayer 205 and bulk region 208. According to some embodiments, both bulk region 208 and sublayer 205 may be a same group IV semiconductor material (such as silicon, germanium, or silicon germanium), group III-V semiconductor material (such as gallium arsenide, indium gallium arsenide, or indium phosphide), and/or any other suitable material upon which transistors can be formed. In some other embodiments, sublayer 205 includes a different semiconductor material than bulk region 208. Buried sacrificial layer 206 includes a different material than sublayer 205 and bulk region 208. According to some embodiments, buried sacrificial layer 206 includes a material that can be selectively removed during a later backside process. In some examples, buried sacrificial layer 206 can include silicon germanium or silicon dioxide. In an example where buried sacrificial layer 206 includes silicon germanium, each of sublayer 205 and bulk region 208 may include silicon. According to some embodiments, sublayer 205 has a thickness between about 10 nm and about 20 nm and buried sacrificial layer 206 has a thickness between about 10 nm and about 20 nm. Bulk region 208 may have any thickness that represents a remaining portion of the wafer, such as any thickness between 1 m and 500 m. According to some embodiments, each of the various layers over bulk region 208 may be epitaxially grown or deposited using any known or proprietary material deposition technique, such as chemical vapor deposition (CVD), plasma-enhanced chemical vapor deposition (PECVD), physical vapor deposition (PVD), or atomic layer deposition (ALD).

According to some embodiments, sacrificial layers 202 have a different material composition than semiconductor layers 204. In some embodiments, sacrificial layers 202 are silicon germanium (SiGe) while semiconductor layers 204 include a semiconductor material suitable for use as a nanosheet such as silicon (Si), SiGe, germanium, or III-V materials like indium phosphide (InP) or gallium arsenide (GaAs). In examples where SiGe is used in each of sacrificial layers 202 and in semiconductor layers 204, the germanium concentration is different between sacrificial layers 202 and semiconductor layers 204. For example, sacrificial layers 202 may include a higher germanium content compared to semiconductor layers 204. In some examples, semiconductor layers 204 may be doped with either n-type dopants (to produce a p-channel transistor) or p-type dopants (to produce an n-channel transistor).

While dimensions can vary from one example embodiment to the next, the thickness of each sacrificial layer 202 may be between about 5 nm and about 20 nm. In some embodiments, the thickness of each sacrificial layer 202 is substantially the same (e.g., within 1-2 nm). The thickness of each of semiconductor layers 204 may be about the same as the thickness of each sacrificial layer 202 (e.g., about 5-20 nm).

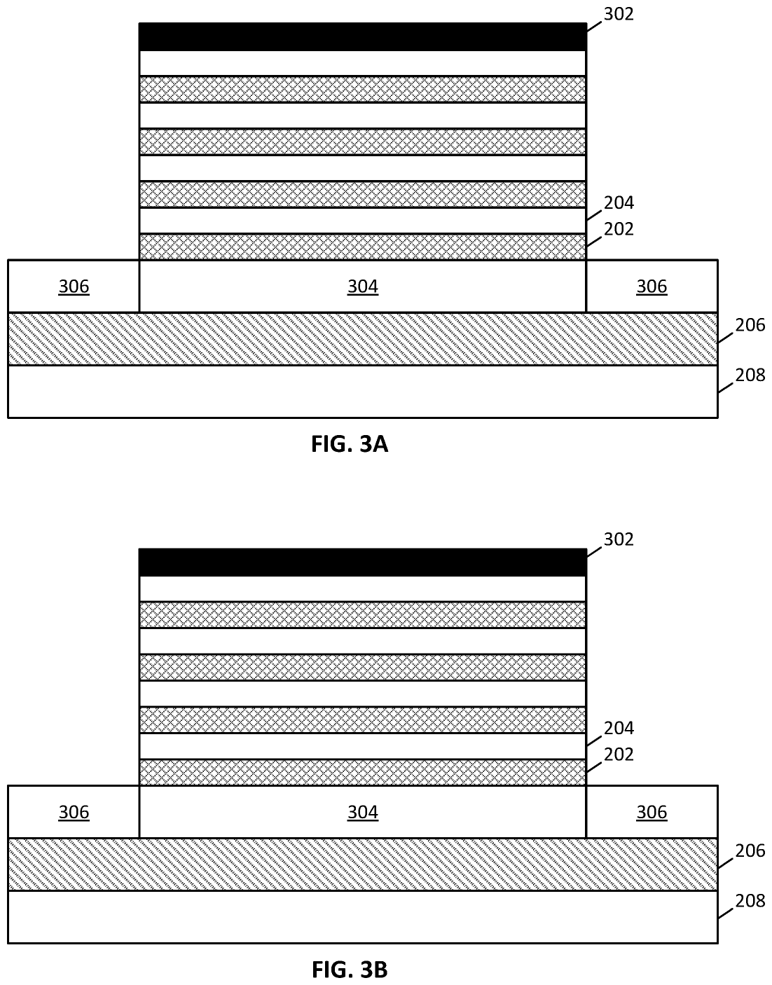

FIGS. 3A and 3B depict the cross-section views of the structure shown in FIGS. 2A and 2B, respectively, following the formation of a cap layer 302 and the subsequent formation of a fin beneath cap layer 302, according to an embodiment. Cap layer 302 may be any suitable hard mask material such as a carbon hard mask (CHM) or silicon nitride. Cap layer 302 is patterned into rows to form corresponding rows of fins from the alternating layer stack of sacrificial layers 202 and semiconductor layers 204. The rows of fins extend lengthwise in a first direction (e.g., into and out of the page of each cross-section view).

According to some embodiments, an anisotropic etching process through the layer stack continues into at least a portion of substrate 201, where the unetched portions of substrate 201 beneath the fin form a subfin region 304. In some embodiments, the etching process extends through an entire thickness of sublayer 205 and stops at buried sacrificial layer 206. Accordingly, subfin region 304 may be a portion of sublayer 205. The etched portions of sublayer 205 may be filled with a dielectric fill 306 that acts as shallow trench isolation (STI) between adjacent fins. Dielectric fill 306 may be any suitable dielectric material such as silicon dioxide, and may be recessed to a desired depth as shown (in this example case, down to around the upper surface of subfin 304), so as to define the active portion of the fin that will be covered by one or more gate structures.

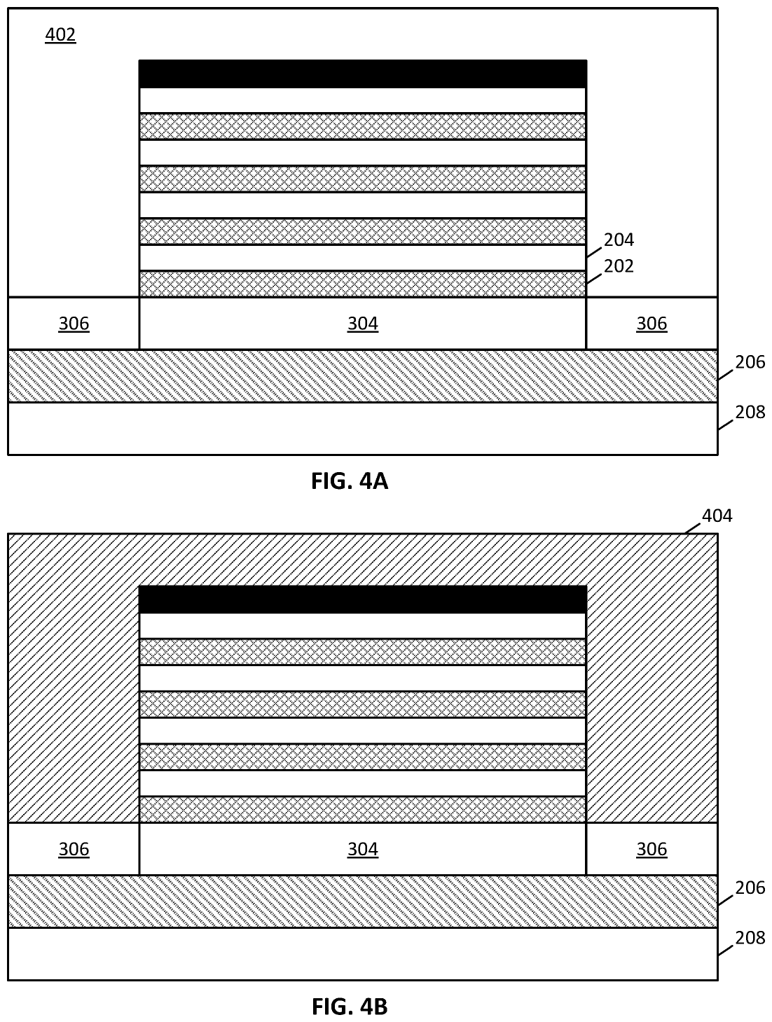

FIGS. 4A and 4B depict the cross-section views of the structure shown in FIGS. 3A and 3B, respectively, following the formation of a sacrificial gate 402 extending across the fin in a second direction different from the first direction, according to some embodiments. Sacrificial gate 402 may extend across the fin in a second direction that is orthogonal to the first direction. According to some embodiments, the sacrificial gate material is formed in parallel strips across the integrated circuit and removed in all areas not protected by a gate masking layer. Sacrificial gate 402 may be any suitable material that can be selectively removed without damaging the semiconductor material of the fin. In some examples, sacrificial gate 402 includes polysilicon.

As seen in the cross-section views, sacrificial gate 402 extends across the fin along the gate trench cross-section of FIG. 4A but is not present along the source/drain trench cross-section of FIG. 4B. Rather, a dielectric fill 404 is formed across the source/drain trench shown in FIG. 4B. A top surface of dielectric fill 404 may be substantially coplanar with a top surface of sacrificial gate 402. Dielectric fill 404 may include any suitable dielectric material, such as silicon dioxide or silicon oxynitride. Dielectric fill 404 may be deposited using CVD.

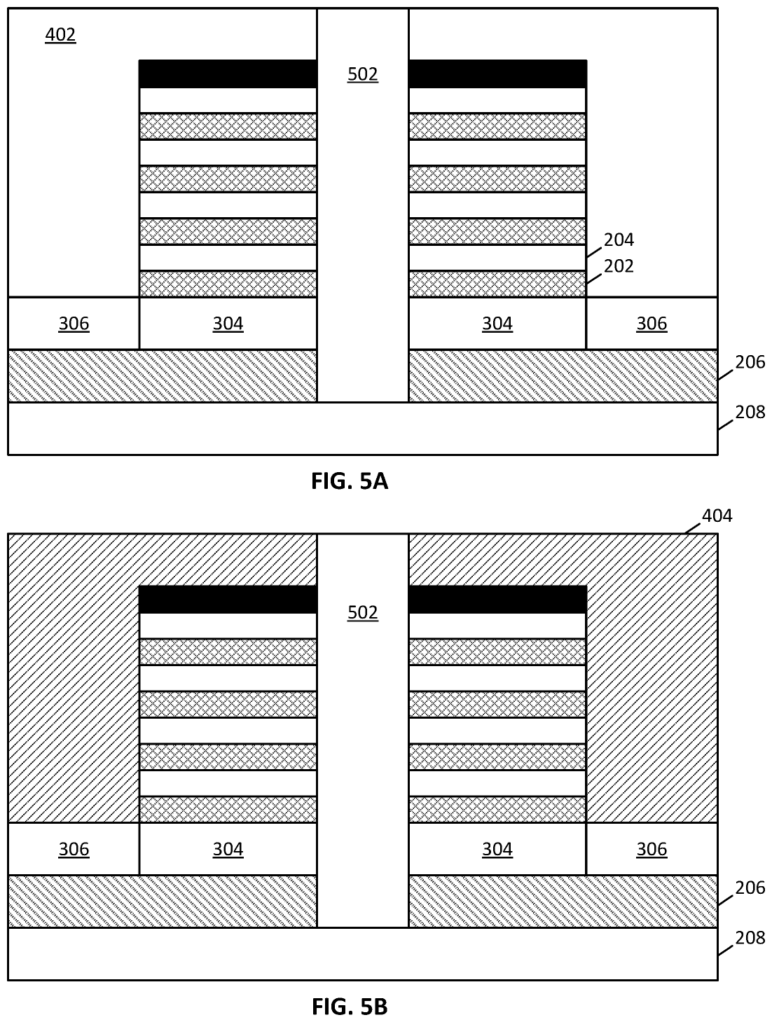

FIGS. 5A and 5B depict the cross-section views of the structure shown in FIGS. 4A and 4B, respectively, following the formation of a dielectric wall 502 bisecting the fin along both the gate trench (FIG. 5A) and the source/drain trench (FIG. 5B), according to some embodiments. An anisotropic RIE process may be used to first form a recess through the fin and through the underlying subfin 304 and buried sacrificial layer 206. The recess may then be filled with a dielectric material or a plurality of dielectric materials to form dielectric wall 502. As noted above, dielectric wall 502 may include silicon nitride, titanium dioxide, aluminum nitride, or aluminum oxide.

According to some embodiments, dielectric wall 502 is aligned such that is cuts the fin into two parts of substantially equal width (e.g., within 3 nm of each other along the second direction) on either side of dielectric wall 502. According to some embodiments, dielectric wall 502 extends through at least an entire thickness of buried sacrificial layer 206. Dielectric wall 502 may extend into a portion of bulk region 208. A top surface of dielectric wall 502 may be polished such that it is substantially coplanar with both sacrificial gate 402 and dielectric fill 404. Dielectric wall 502 may have a width along the second direction between about 5 nm and about 30 nm.

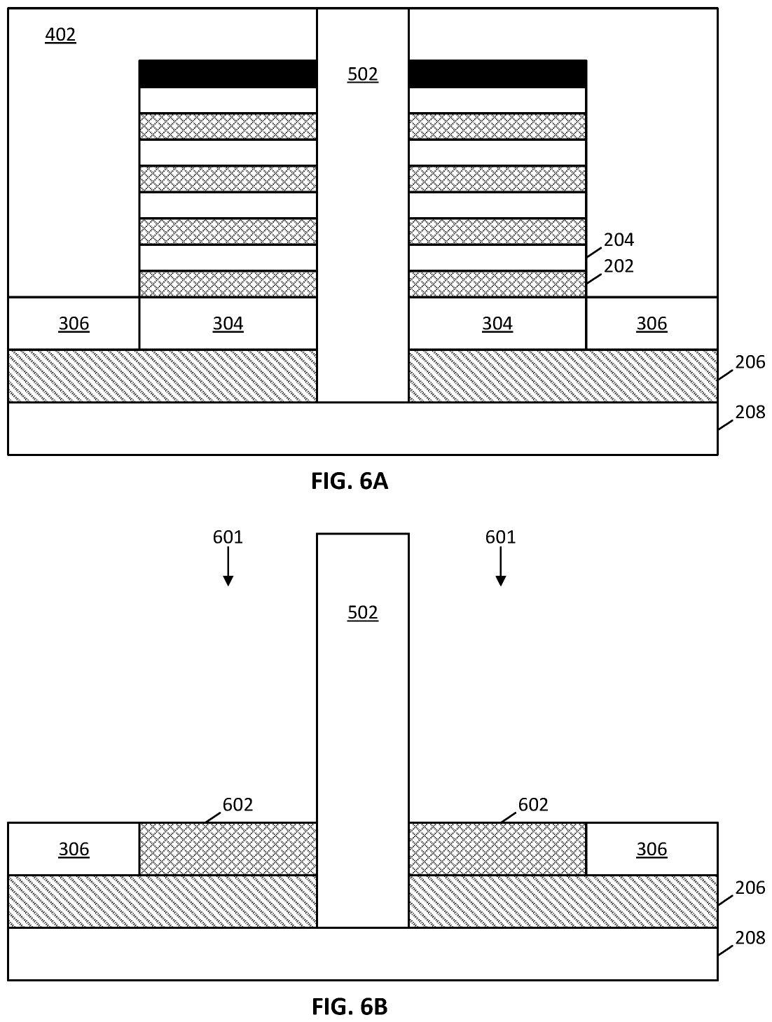

FIGS. 6A and 6B depict the cross-section views of the structure shown in FIGS. 5A and 5B, respectively, following the formation of recesses 601 through the fin on either side of dielectric wall 502 along the source/drain trench, according to an embodiment. Dielectric fill 404 may first be removed to expose the fin on either side of dielectric wall 502 along the source/drain trench. According to some embodiments, both semiconductor layers 204 and sacrificial layers 202 are etched at substantially the same rate using an anisotropic RIE process to remove the portions of the fin not protected by sacrificial gate 402. According to some embodiments, the fin etching process continues through the exposed subfin 304 along the source/drain trench. An entire thickness of the exposed subfin 304 may be removed (e.g., stopping at buried sacrificial layer 206) and replaced with sacrificial plugs 602. Sacrificial plug 602 may include any material that has a high degree of etch selectivity with the material of dielectric wall 502 and dielectric fill 306. In some examples, sacrificial plug 602 includes titanium nitride (TiN). According to some embodiments, sacrificial plug 602 is recessed to a given thickness such that a top surface of sacrificial plug 602 is substantially coplanar with a top surface of dielectric fill 306.

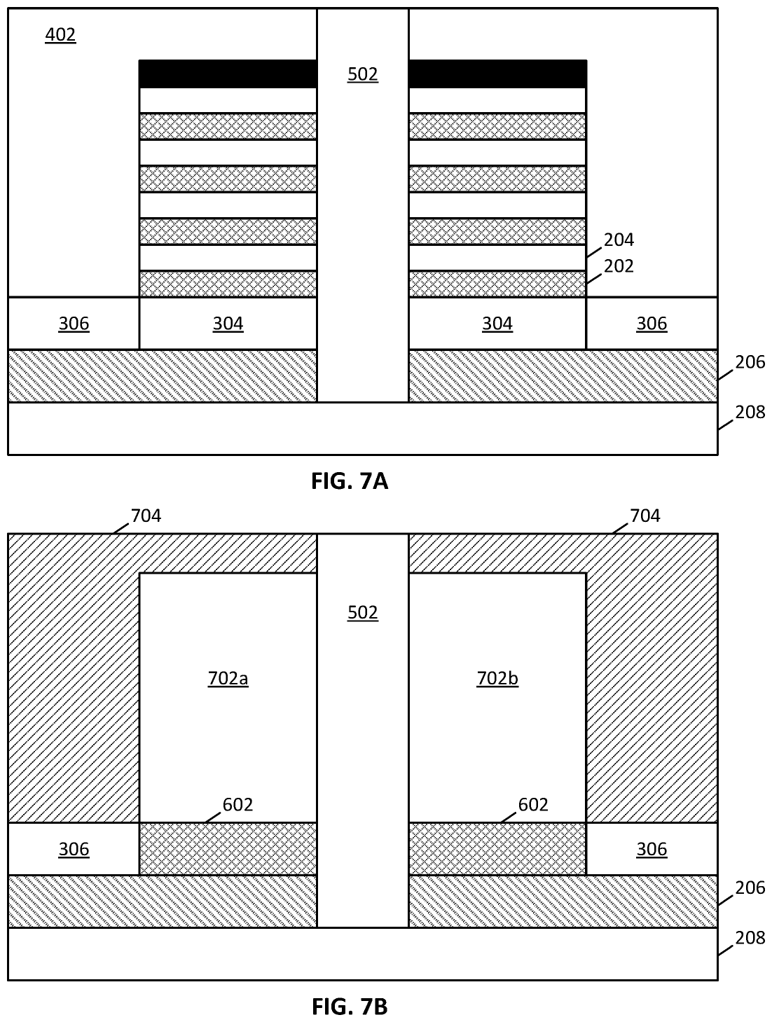

FIGS. 7A and 7B depict the cross-section views of the structure shown in FIGS. 6A and 6B, respectively, following the formation of source or drain regions 702a/702b within the source/drain trench, according to some embodiments. Source or drain regions 702a/702b may be epitaxially grown from the exposed ends of semiconductor layers 204 on either side of dielectric wall 502, such that the material grows together or otherwise merges together along the height of the fin, according to some embodiments. In other embodiments, the epitaxial growth may only partially merge, or not merge at all thereby leaving space between the laterally adjacent epi-growths in which contact material can be deposited. Such embodiments may further increase contact surface area and thus further lower contact resistance. Further note that epitaxial growth on one semiconductor layer 204 can fully or partially merge with epitaxial growth on one or more other semiconductor layers 204 in the same vertical stack. The degree of any such merging can vary from one embodiment to the next. In the example of a PMOS device, a given source or drain region may be a semiconductor material (e.g., group IV or group III-V semiconductor materials) having a higher dopant concentration of p-type dopants compared to n-type dopants. In the example of an NMOS device, a given source or drain region may be a semiconductor material (e.g., group IV or group III-V semiconductor materials) having a higher dopant concentration of n-type dopants compared to p-type dopants. As seen in FIG. 7B, source or drain regions 702a/702b may be grown directly over sacrificial plugs 602, such that a bottom surface of source or drain regions 702a/702b contacts a top surface of sacrificial plugs 602.

According to some embodiments, a dielectric fill 704 is formed over and/or around source or drain regions 702a/702b along the source/drain trench. Dielectric fill 704 may be substantially the same as dielectric fill 404 and a top surface of dielectric fill 704 may be polished to be substantially coplanar with a top surface of sacrificial gate 402.

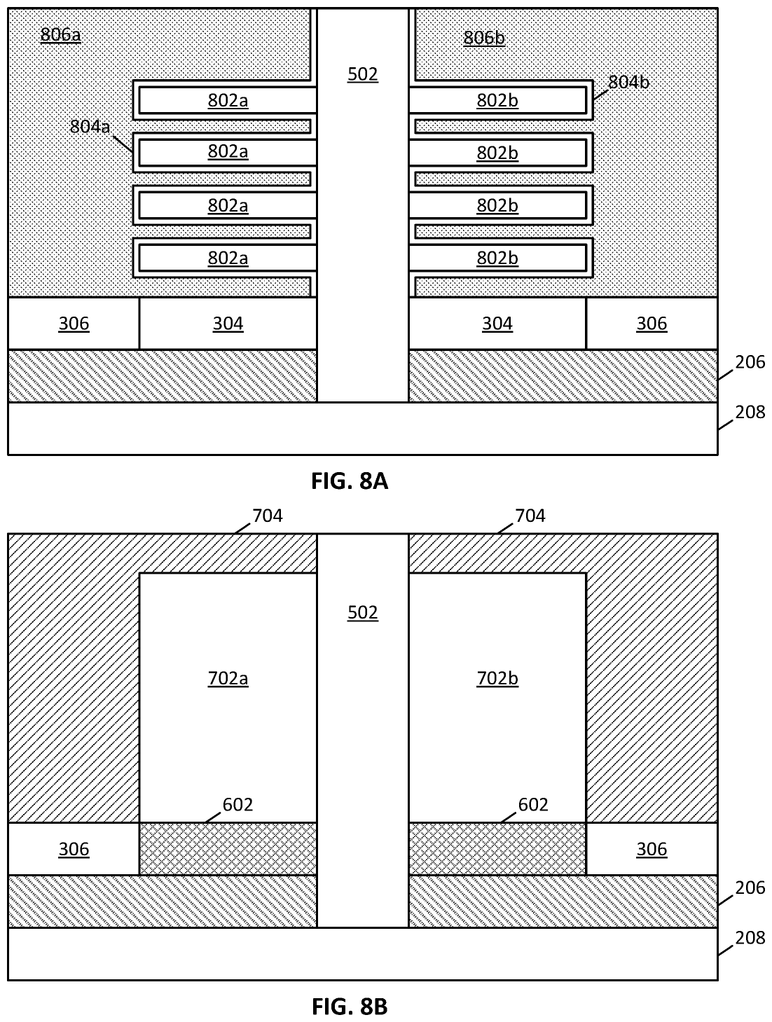

FIGS. 8A and 8B depict the cross-section views of the structure shown in FIGS. 7A and 7B, respectively, following the formation of nanosheets 802a/802b and corresponding gate structures around nanosheets 802a/802b, according to some embodiments. Depending on the dimensions of the structures, nanosheets 802a/802b may also be considered nanowires or nanoribbons. Sacrificial gate 402 may be removed using any wet or dry isotropic process thus exposing the alternating layer stack of the fins on either side of dielectric wall 502 within the gate trench left behind after the removal of sacrificial gate 402. Once sacrificial gate 402 is removed, sacrificial layers 202 may also be removed using a selective isotropic etching process that removes the material of sacrificial layers 202 but does not remove (or removes very little of) semiconductor layers 204. At this point, the suspended (sometimes called released) semiconductor layers 204 form nanosheets 802a that extend from source or drain region 702a and nanosheets 802b that extend from source or drain region 702b.

As noted above, a first gate structure includes a first gate dielectric 804a and a first gate electrode 806a while a second gate structure includes a second gate dielectric 804b and a second gate electrode 806b. The gate dielectric 804a/804b may be conformally deposited around corresponding nanosheets 802a/802b using any suitable deposition process, such as atomic layer deposition (ALD). According to some embodiments, gate dielectric 804a/804b also forms along the sidewalls of dielectric wall 502. Gate dielectric 804a/804b may include any suitable dielectric (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, the gate dielectric is hafnium oxide with a thickness between about 1 nm and about 5 nm. In some embodiments, gate dielectric 804a/804b may include one or more silicates (e.g., titanium silicate, tungsten silicate, niobium silicate, and silicates of other transition metals). Gate dielectric 804a/804b may be a multilayer structure, in some examples. For instance, gate dielectric 804a/804b may include a first layer on nanosheets 802a/802b, and a second layer on the first layer. The first layer can be, for instance, an oxide of the semiconductor layers (e.g., silicon dioxide) and the second layer can be a high-k dielectric material (e.g., hafnium oxide). In some embodiments, an annealing process may be carried out on gate dielectric 804a/804b to improve its quality when a high-k dielectric material is used. In some embodiments, the high-k material can be nitridized to improve its aging resistance.

According to some embodiments, gate electrode 806a/806b may be deposited over and around the corresponding gate dielectric 804a/804b and can be any gate structure that may include any number of gate cuts. In some embodiments, gate electrode 806a/806b includes doped polysilicon, a metal, or a metal alloy. Example suitable metals or metal alloys include aluminum, tungsten, cobalt, molybdenum, ruthenium, titanium, tantalum, copper, and carbides and nitrides thereof. The gate electrode may include, for instance, one or more workfunction layers, resistance-reducing layers, and/or barrier layers. The workfunction layers can include, for example, p-type workfunction materials (e.g., titanium nitride) for PMOS gates, or n-type workfunction materials (e.g., titanium aluminum carbide) for NMOS gates.

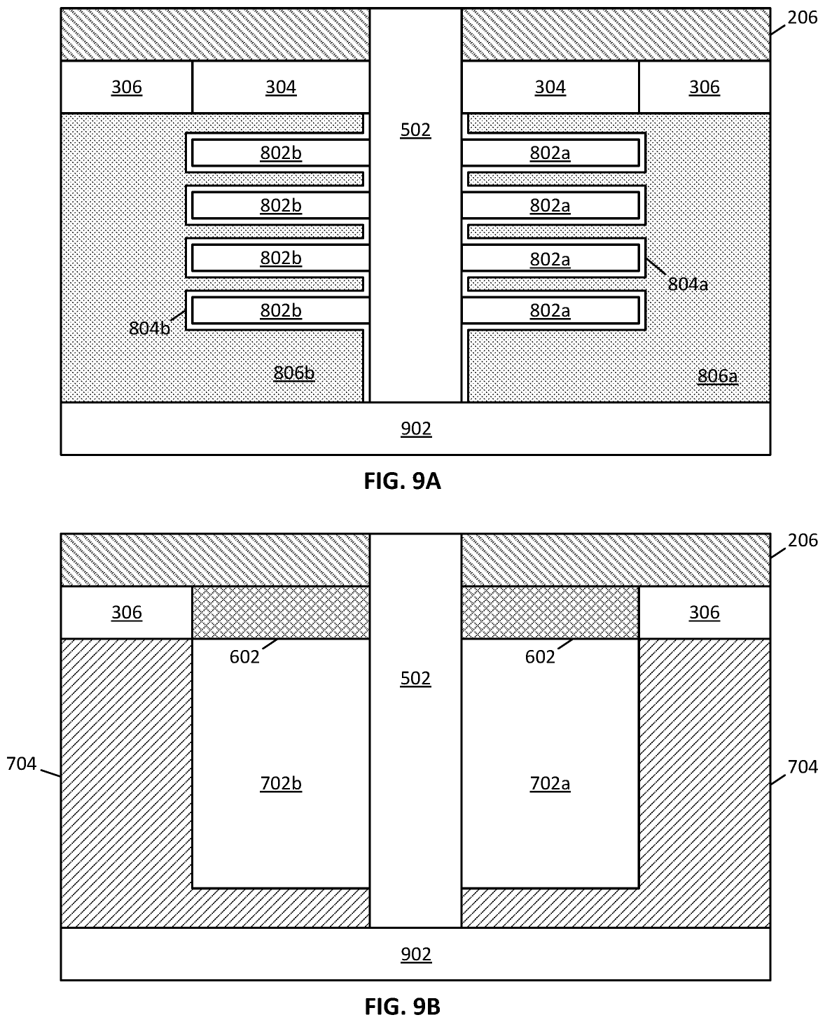

FIGS. 9A and 9B depict the cross-section views of the structure shown in FIGS. 8A and 8B, respectively, following the bonding of the structure to a handle wafer 902 and the subsequent removal of the substrate bulk region 208, according to some embodiments.

The structure has been flipped over in FIGS. 9A and 9B compared to FIGS. 8A and 8B to indicate that backside processing is now being performed. Note that the relative terms over and under are also now applied to the new orientation shown in the figures. It should be understood that any number of interconnect layers including dielectric layers and conductive structures may be present between the semiconductor devices and handle wafer 902. Such a frontside interconnect structure is not shown for clarity. Bulk region 208 may be removed using any anisotropic etching process or polishing process. According to some embodiments, bulk region 208 is removed until a surface of buried sacrificial layer 206 is exposed.

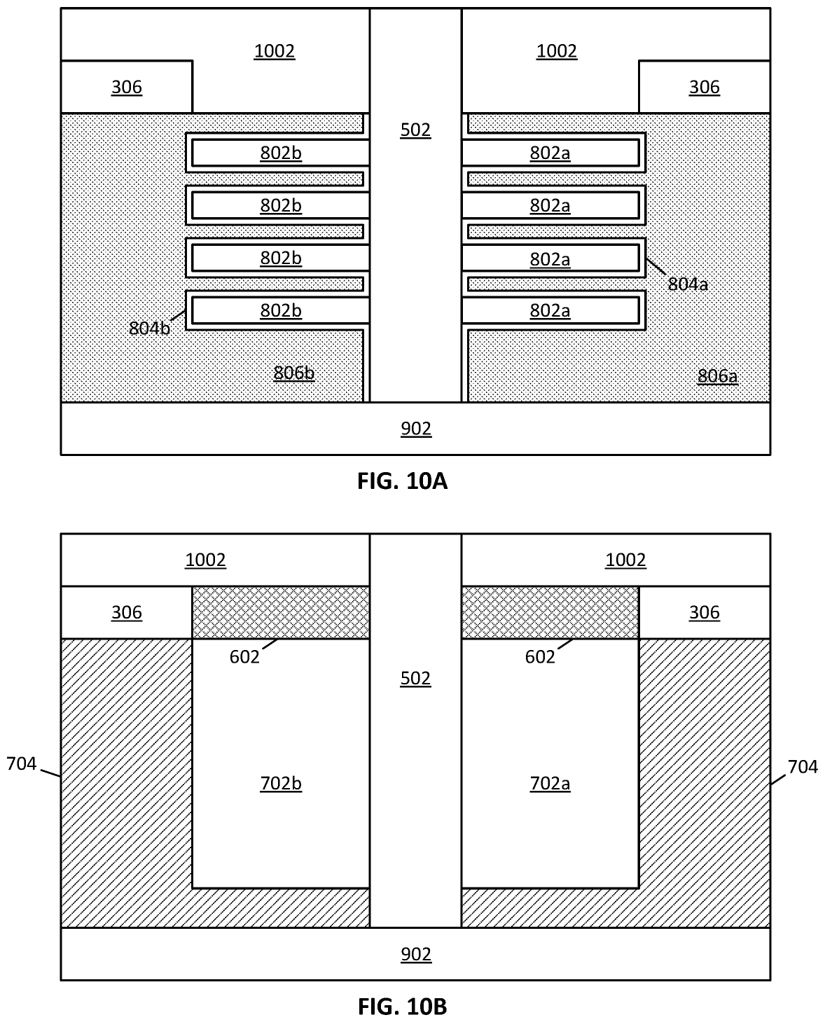

FIGS. 10A and 10B depict the cross-section views of the structure shown in FIGS. 9A and 9B, respectively, following the removal of buried sacrificial layer 206 and subfin 304, and the subsequent formation of backside dielectric fill 1002, according to some embodiments. Buried sacrificial layer 206 may be selectively removed using any suitable isotropic etching process. The removal of buried sacrificial layer 206 exposes subfins 304 along the gate trench and sacrificial plugs 602 along the source/drain trench. According to some embodiments, subfins 304 may also be removed using another isotropic etching process. In other examples, subfins 304 are not removed and remain in the final structure. Backside dielectric fill 1002 is formed over sacrificial plugs 602 along the source/drain trench and also within the recess left behind from the removal of subfins 304. According to some embodiments, a top surface of backside dielectric fill 1002 may be polished to be substantially coplanar with a top surface of dielectric wall 502.

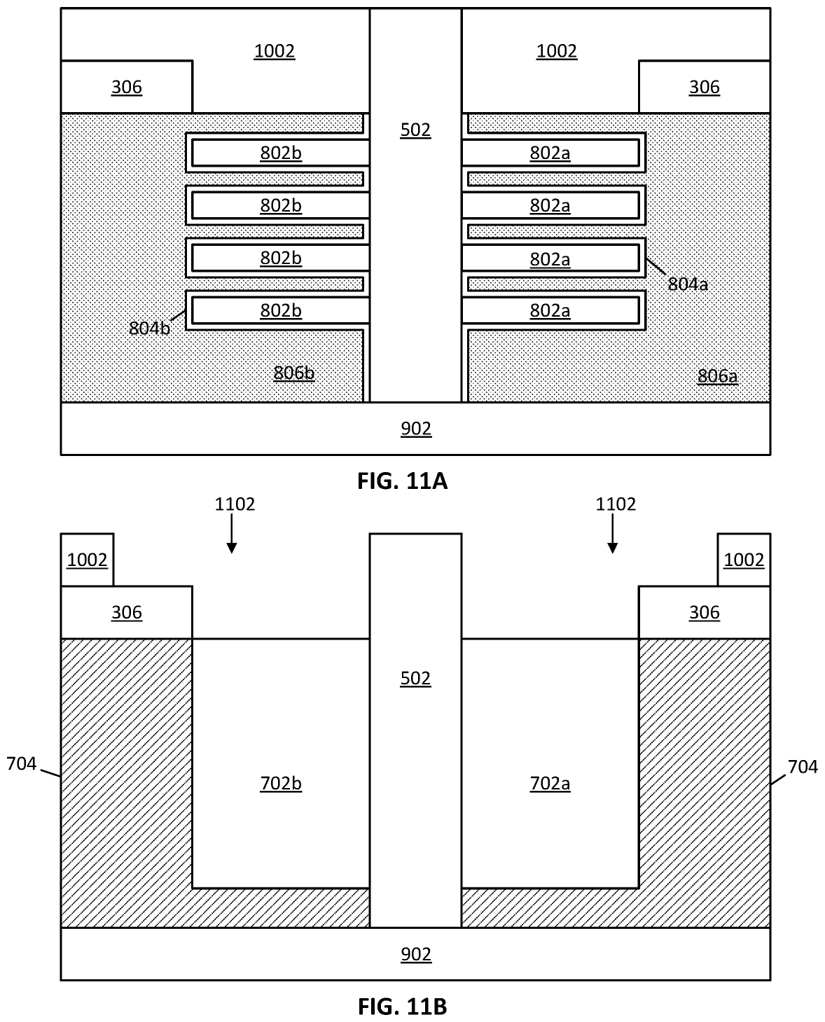

FIGS. 11A and 11B depict the cross-section views of the structure shown in FIGS. 10A and 10B, respectively, following the opening of recesses 1102 through portions of backside dielectric fill 1002 along the source/drain trench and the removal of sacrificial plugs 602, according to some embodiments. Any suitable isotropic etching process may be used to form recesses 1102 through an entire thickness of backside dielectric fill 1002 along the source/drain trench. In some embodiments, portions of backside dielectric fill 1002 along the gate trench may also be etched such that recesses 1102 also extend across the gate trench. The exposed sacrificial plugs 602 may be removed using any suitable isotropic etching process to expose backside surfaces of source or drain regions 702a/702b.

FIGS. 12A and 12B depict the cross-section views of the structure shown in FIGS. 11A and 11B, respectively, following the formation of first conductive structure 1202a and second conductive structure 1202b within recesses 1102 and on the exposed surfaces of corresponding source or drain regions 702a/702b, according to some embodiments. Conductive structures 1202a/1202b may provide both a conductive contact (adjacent to dielectric fill 306) and a conductive layer (adjacent to backside dielectric fill 1002) within the same monolithic structure (e.g., using a dual-damascene process). In other examples, conductive contacts are formed first adjacent to dielectric fill 306 on either side of dielectric wall 502 followed by conductive layers adjacent to backside dielectric fill 1002 on either side of dielectric wall 502. Conductive structures 1202a/1202b may include any suitable conductive material, such as tungsten, cobalt, ruthenium, copper, titanium, molybdenum, or any alloys thereof. Conductive structures 1202a/1202b may include any number of additional layers, such as barrier layers and/or resistance-lowering layers. According to some embodiments, dielectric wall 502 extends between first conductive structure 1202a and second conductive structure 1202b to physically separate the structures. In some examples, first conductive structure 1202a directly contacts one side of dielectric wall 502 and second conductive structure 1202b directly contacts the opposite side of dielectric wall 502. Due to the presence of dielectric wall 502, conductive structures 1202a/1202b may be self-aligned over source or drain regions 702a and 702b and are electrically isolated from one another, according to some embodiments. A top surface of conductive structures 1202a/1202b may be polished to be substantially coplanar with a top surface of dielectric wall 502 and/or backside dielectric fill 1002.

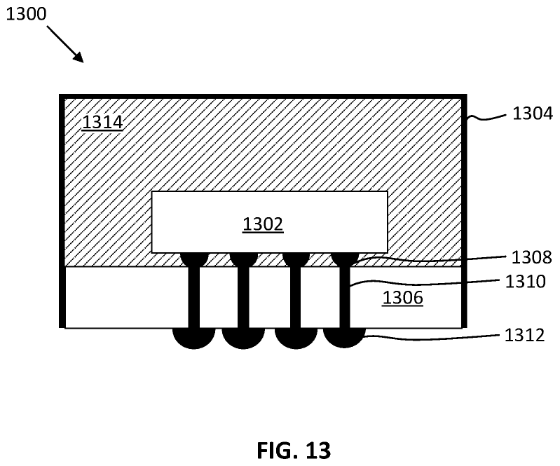

FIG. 13 illustrates an example embodiment of a chip package 1300. As can be seen, chip package 1300 includes one or more dies 1302. One or more dies 1302 may include at least one integrated circuit having semiconductor devices, such as any of the semiconductor devices disclosed herein. One or more dies 1302 may include any other circuitry used to interface with other devices formed on the dies, or other devices connected to chip package 1300, in some example configurations.

As can be further seen, chip package 1300 includes a housing 1304 that is bonded to a package substrate 1306. The housing 1304 may be housing, and provides, for example, electromagnetic shielding and environmental protection for the components of chip package 1300. The one or more dies 1302 may be conductively coupled to a package substrate 1306 using connections 1308, which may be implemented with any number of connection mechanisms, such as solder bumps, ball grid array (BGA), pins, or wire bonds, to name a few examples. Package substrate 1306 may be any package substrate, but in some cases includes a dielectric material having conductive pathways (e.g., including conductive vias and lines) extending through the dielectric material between the faces of package substrate 1306, or between different locations on each face. In some embodiments, package substrate 1306 may have a thickness less than 1 millimeter (e.g., between 0.1 millimeters and 0.5 millimeters), although any number of package geometries can be used. Additional conductive contacts 1312 may be disposed at an opposite face of package substrate 1306 for conductively contacting, for instance, a printed circuit board (PCB). One or more vias 1310 extend through a thickness of package substrate 1306 to provide conductive pathways between one or more of connections 1308 to one or more of contacts 1312. Vias 1310 are illustrated as single straight columns through package substrate 1306 for ease of illustration, although other configurations can be used (e.g., damascene, dual damascene, through-silicon via). In still other embodiments, vias 1310 are fabricated by multiple smaller stacked vias, or are staggered at different locations across package substrate 1306. In the illustrated embodiment, contacts 1312 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 1312, to inhibit shorting.

In some embodiments, a mold material 1314 may be disposed around the one or more dies 1302 included within housing 1304 (e.g., between dies 1302 and package substrate 1306 as an underfill material, as well as between dies 1302 and housing 1304 as an overfill material). Although the dimensions and qualities of the mold material 1314 can vary from one embodiment to the next, in some embodiments, a thickness of mold material 1314 is less than 1 millimeter. Example materials that may be used for mold material 1314 include epoxy mold materials, as suitable. In some cases, the mold material 1314 is thermally conductive, in addition to being electrically insulating.

### Methodology

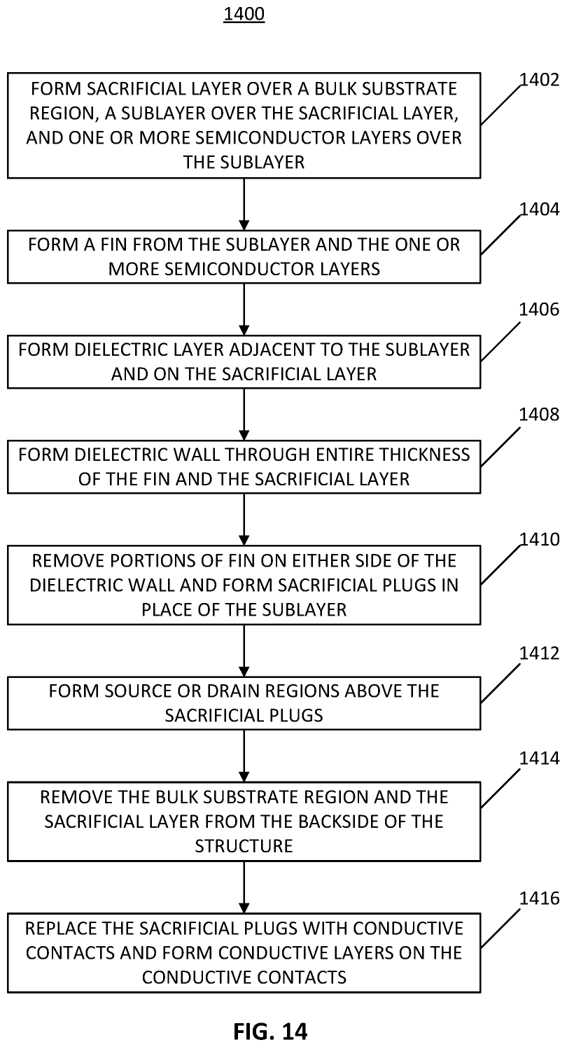

FIG. 14 is a flow chart of a method 1400 for forming at least a portion of an integrated circuit, according to an embodiment. Various operations of method 1400 may be illustrated in FIGS. 2A-12A and 2B-12B. However, the correlation of the various operations of method 1400 to the specific components illustrated in the aforementioned figures is not intended to imply any structural and/or use limitations. Rather, the aforementioned figures provide one example embodiment of method 1400. Other operations may be performed before, during, or after any of the operations of method 1400. Some of the operations of method 1400 may be performed in a different order than the illustrated order.

Method 1400 begins with operation 1402 where a stack of different material layers are formed over a bulk substrate region. According to some embodiments, the material layers include a sacrificial layer, a sublayer over the sacrificial layer, and one or more semiconductor layers over the sublayer. According to some embodiments, both the bulk substrate region and the sublayer are a same group IV semiconductor material (such as silicon, germanium, or silicon germanium), group III-V semiconductor material (such as gallium arsenide, indium gallium arsenide, or indium phosphide), and/or any other suitable material upon which transistors can be formed. The sacrificial layer includes a different material than the sublayer and the bulk substrate region. In some examples, the sacrificial layer can include silicon germanium or silicon dioxide. In an example where the sacrificial layer includes silicon germanium, each of the sublayer and the bulk substrate region may include silicon. According to some embodiments, both the sublayer and the sacrificial layer has a thickness between about 10 nm and about 20 nm while the bulk substrate region has any thickness that represents a remaining portion of the wafer, such as any thickness between 1 m and 500 m. According to some embodiments, each of the various layers over the bulk substrate region may be epitaxially grown or deposited using any known or proprietary material deposition technique, such CVD, PECVD, PVD, or ALD.

Method 1400 continues with operation 1404 where at least one semiconductor fin is formed, according to some embodiments. The semiconductor material in the at least one fin may be formed from at least the sublayer and the one or more semiconductor layers above the sacrificial layer. In some embodiments, the at least one fin includes alternating layers of material (e.g., alternating layers of silicon and SiGe) that facilitates forming of nanosheets and nanoribbons during a gate forming process where one type of the alternating layers are selectively etched away so as to liberate the other type of alternating layers within the channel region, so that a gate-forming process can then be carried out. The portion of the fin formed from the sublayer may be considered a subfin portion.

Method 1400 continues with operation 1406 where a dielectric layer is formed adjacent to the subfin portion of the fin and one the sacrificial layer. The dielectric layer may include silicon oxide. According to some embodiments, the dielectric layer acts as an STI region between the fin and any adjacent fins. According to some embodiments, each semiconductor device includes a subfin portion beneath a fin of alternating semiconductor layers and adjacent to the dielectric layer.

Method 1400 continues with operation 1408 where a dielectric wall is formed through an entire thickness of the fin and the underlying sacrificial layer. An anisotropic RIE process may be used to first form a recess through the fin and through the underlying sacrificial layer. The recess may then be filled with a dielectric material or a plurality of dielectric materials to form the dielectric wall. The dielectric wall may include silicon nitride, titanium dioxide, aluminum nitride, or aluminum oxide, to name a few examples.

According to some embodiments, the dielectric wall is aligned such that is cuts the fin into two parts of substantially equal width (e.g., within 3 nm of each other) on either side of the dielectric wall. According to some embodiments, the dielectric wall also extends into a portion of the bulk substrate region beneath the sacrificial layer.

Method 1400 continues with operation 1410 where portions of the fin on either side of the dielectric wall are removed in areas where source or drain regions are to be formed. According to some embodiments, the fins are removed including the subfin (e.g., sublayer) portions of the fins and the removed subfin portions are replaced with sacrificial plugs. According to some embodiments, the one or more semiconductor layers of the fin may be removed using an anisotropic RIE process. According to some embodiments, the fin etching process continues through the exposed subfin along the source/drain trench. An entire thickness of the exposed subfin may be removed (e.g., stopping at the sacrificial layer) and replaced with sacrificial plugs. According to some embodiments, the sacrificial plugs may include any material that has a high degree of etch selectivity with the material of the dielectric wall and the adjacent dielectric layer. In some examples, the sacrificial plugs include titanium nitride (TiN).

Method 1400 continues with operation 1412 where source or drain regions are formed over the sacrificial plugs. The source or drain regions may be epitaxially grown from the exposed ends of semiconductor layers from the portions of the fin on either side of the dielectric wall. In the example of a PMOS device, the source or drain region may be a semiconductor material (e.g., group IV or group III-V semiconductor materials) having a higher dopant concentration of p-type dopants compared to n-type dopants. In the example of an NMOS device, the source or drain region may be a semiconductor material (e.g., group IV or group III-V semiconductor materials) having a higher dopant concentration of n-type dopants compared to p-type dopants. The source or drain regions may contact the underlying sacrificial plugs. According to some embodiments, a dielectric fill may be formed over and/or around the source or drain regions.

Method 1400 continues with operation 1414 where the bulk substrate region and the sacrificial layer are removed from the backside of the structure. In some examples, a handle wafer is first bonded to the frontside of the structure before removing the bulk substate region. The bulk substrate region may be removed using any anisotropic etching process or grinding process using, for example, chemical mechanical polishing (CMP). According to some embodiments, the bulk substrate region is removed until a surface of the sacrificial layer is exposed. A separate etching process may be performed to remove the sacrificial layer, yielding an end of the dielectric wall extending away from the rest of the structure. The sacrificial layer may be removed using any suitable isotropic etching process to expose the sacrificial plugs.

Method 1400 continues with operation 1416 where the sacrificial plugs are removed and replaced with conductive contacts. According to some embodiments, conductive layers are further formed over the conductive contacts and the dielectric wall physically separates the conductive contacts and the conductive layers beneath adjacent source or drain regions. The conductive contacts and the conductive layers may be formed at the same time (e.g., from the same material deposited at the same time), or they may be formed of different materials and/or at different times. The conductive contacts and the conductive layers may include any suitable conductive material such as tungsten, cobalt, ruthenium, copper, titanium, molybdenum, or any alloys thereof.

### Example System

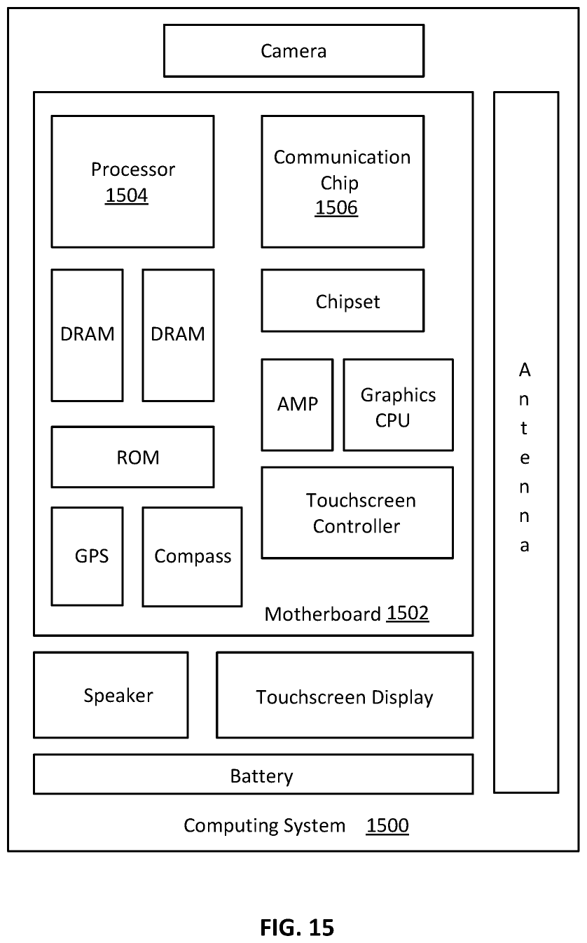

FIG. 15 is an example computing system implemented with one or more of the integrated circuit structures as disclosed herein, in accordance with some embodiments of the present disclosure. As can be seen, the computing system 1500 houses a motherboard 1502. The motherboard 1502 may include a number of components, including, but not limited to, a processor 1504 and at least one communication chip 1506, each of which can be physically and electrically coupled to the motherboard 1502, or otherwise integrated therein. As will be appreciated, the motherboard 1502 may be, for example, any printed circuit board (PCB), whether a main board, a daughterboard mounted on a main board, or the only board of system 1500, etc.

Depending on its applications, computing system 1500 may include one or more other components that may or may not be physically and electrically coupled to the motherboard 1502. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1500 may include one or more integrated circuit structures or devices configured in accordance with an example embodiment (e.g., a module including an integrated circuit device on a substrate, the substrate having one or more semiconductor devices with backside contacts to source or drain regions that are separated by a dielectric wall, as variously provided herein). In some embodiments, multiple functions can be integrated into one or more chips (e.g., for instance, note that the communication chip 1506 can be part of or otherwise integrated into the processor 1504).

The communication chip 1506 enables wireless communications for the transfer of data to and from the computing system 1500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1506 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1500 may include a plurality of communication chips 1506. For instance, a first communication chip 1506 may be dedicated to shorter range wireless communications such as Wi-Fi and Bluetooth and a second communication chip 1506 may be dedicated to longer range wireless communications such as GPS, EDGE, GPRS, CDMA, WiMAX, LTE, Ev-DO, and others.

The processor 1504 of the computing system 1500 includes an integrated circuit die packaged within the processor 1504. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 1506 also may include an integrated circuit die packaged within the communication chip 1506. In accordance with some such example embodiments, the integrated circuit die of the communication chip includes one or more semiconductor devices as variously described herein. As will be appreciated in light of this disclosure, note that multi-standard wireless capability may be integrated directly into the processor 1504 (e.g., where functionality of any chips 1506 is integrated into processor 1504, rather than having separate communication chips). Further note that processor 1504 may be a chip set having such wireless capability. In short, any number of processor 1504 and/or communication chips 1506 can be used. Likewise, any one chip or chip set can have multiple functions integrated therein.

In various implementations, the computing system 1500 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 1500 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a first semiconductor device having a first semiconductor region extending in a first direction from a first source or drain region, and a first gate structure extending in a second direction over the first semiconductor region, and a second semiconductor device having a second semiconductor region extending in the first direction from a second source or drain region, and a second gate structure extending in the second direction over the second semiconductor region. The second source or drain region is adjacent to the first source or drain region along the second direction. The integrated circuit also includes a first conductive contact on an underside of the first source or drain region, a second conductive contact on an underside of the second source or drain region, and a dielectric wall extending in the first direction between and contacting both the first semiconductor region and the second semiconductor region, and extending between both the first source or drain region and the second source or drain region. The dielectric wall further extends in a third direction along at least an entire thickness of the first conductive contact and the second conductive contact.

Example 2 includes the integrated circuit of Example 1, wherein the dielectric wall directly contacts a sidewall of the first conductive contact and a sidewall of the second conductive contact.

Example 3 includes the integrated circuit of Example 1 or 2, further comprising a first conductive layer on the first conductive contact and a second conductive layer on the second conductive contact, wherein the dielectric wall extends in the third direction between the first conductive layer and the second conductive layer.

Example 4 includes the integrated circuit of any one of Examples 1-3, further comprising a first dielectric fill on a topside of the first source or drain region and a second dielectric fill on a topside of the second source or drain region, wherein the dielectric wall extends in the third direction between the first dielectric fill and the second dielectric fill.

Example 5 includes the integrated circuit of any one of Examples 1-4, further comprising a dielectric layer adjacent to the first conductive contact and the second conductive contact.

Example 6 includes the integrated circuit of Example 5, wherein the dielectric layer comprises silicon and oxygen.

Example 7 includes the integrated circuit of any one of Examples 1-6, wherein the dielectric wall comprises silicon and nitrogen.

Example 8 includes the integrated circuit of any one of Examples 1-7, wherein the dielectric wall has a width in the second direction between about 5 nm and about 30 nm.

Example 9 includes the integrated circuit of any one of Examples 1-8, wherein the first semiconductor region comprises a plurality of first semiconductor nanosheets and the second semiconductor region comprises a plurality of second semiconductor nanosheets.

Example 10 includes the integrated circuit of Example 9, wherein the plurality of first semiconductor nanosheets and the plurality of second semiconductor nanosheets comprise germanium, silicon, or a combination thereof.

Example 11 includes the integrated circuit of any one of Examples 1-10, wherein the second direction is substantially perpendicular to the first direction and wherein the third direction is substantially perpendicular to both the first and second directions.

Example 12 is a printed circuit board comprising the integrated circuit of any one of Examples 1-11.

Example 13 is an electronic device that includes a chip package comprising one or more dies. At least one of the one or more dies includes a first semiconductor device having a first semiconductor region extending in a first direction between a first source or drain region and a second source or drain region, and a first gate structure extending in a second direction over the first semiconductor region, and a second semiconductor device having a second semiconductor region extending in the first direction between a third source or drain region and a fourth source or drain region, and a second gate structure extending in the second direction over the second semiconductor region. The at least one of the one or more dies further includes a first conductive contact on an underside of the first source or drain region, a second conductive contact on an underside of the third source or drain region, and a dielectric wall extending in the first direction between and contacting both the first semiconductor region and the second semiconductor region, extending in the first direction between the first source or drain region and the third source or drain region, and extending in the first direction between the second source or drain region and the fourth source or drain region. The dielectric wall further extends in a third direction along at least an entire thickness of the first conductive contact and the second conductive contact.

Example 14 includes the electronic device of Example 13, wherein the dielectric wall directly separates the first conductive contact from the second conductive contact.

Example 15 includes the electronic device of Example 13 or 14, further comprising a first conductive layer on the first conductive contact and a second conductive layer on the second conductive contact, wherein the dielectric wall extends in the third direction directly between the first conductive layer and the second conductive layer.

Example 16 includes the electronic device of any one of Examples 13-15, further comprising a first dielectric fill on a topside of the first source or drain region and a second dielectric fill on a topside of the third source or drain region, wherein the dielectric wall extends in the third direction directly between the first dielectric fill and the second dielectric fill.

Example 17 includes the electronic device of any one of Examples 13-16, further comprising a dielectric layer adjacent to the first conductive contact and the second conductive contact.

Example 18 includes the electronic device of Example 17, wherein the dielectric layer comprises silicon and oxygen.

Example 19 includes the electronic device of any one of Examples 13-18, wherein the dielectric wall comprises silicon and nitrogen.

Example 20 includes the electronic device of any one of Examples 13-19, wherein the dielectric wall has a width in the second direction between about 5 nm and about 30 nm.

Example 21 includes the electronic device of any one of Examples 13-20, wherein the first semiconductor region comprises a plurality of first semiconductor nanosheets and the second semiconductor region comprises a plurality of second semiconductor nanosheets.

Example 22 includes the electronic device of Example 21, wherein the plurality of first semiconductor nanosheets and the plurality of second semiconductor nanosheets comprise germanium, silicon, or a combination thereof.

Example 23 includes the electronic device of any one of Examples 13-22, wherein the second direction is substantially perpendicular to the first direction and wherein the third direction is substantially perpendicular to both the first and second directions.

Example 24 includes the electronic device of any one of Examples 13-23, further comprising a printed circuit board, wherein the chip package is coupled to the printed circuit board.

Example 25 is a method of forming an integrated circuit. The method includes forming a sacrificial layer over a substrate; forming a sublayer on the sacrificial layer and one or more semiconductor layers on the sublayer; forming a fin from the one or more semiconductor layers and the sublayer extending above the sacrificial layer; forming a dielectric layer adjacent to the sublayer and on the sacrificial layer; forming a dielectric wall through an entire thickness of the fin and through an entire thickness of the sacrificial layer; removing portions of the one or more semiconductor layers and the sublayer on either side of the dielectric wall, thus exposing the underlying sacrificial layer; forming a first sacrificial plug on an exposed portion of the sacrificial layer and a second sacrificial plug on another exposed portion of the sacrificial layer, wherein the dielectric wall is between the first sacrificial plug and the second sacrificial plug; forming source or drain regions above the first and second sacrificial plugs; removing the substrate to expose a backside of the sacrificial layer; removing the sacrificial layer; replacing the first and second sacrificial plugs with first and second conductive plugs, respectively; and forming a first conductive layer on the first conductive plug and a second conductive layer on the second conductive plug, wherein the dielectric wall separates the first conductive layer from the second conductive layer.

Example 26 includes the method of Example 25, wherein the one or more semiconductor layers includes an alternating stack of first semiconductor layer and second semiconductor layers, the method further comprising removing the second semiconductor layers to form first suspended nanosheets on one side of the dielectric wall from the first semiconductor layers and to form second suspended nanosheets on an opposite side of the dielectric wall from the first semiconductor layers.

Example 27 includes the method of Example 26, further comprising forming a first gate structure around the first suspended nanosheets and forming a second gate structure around the second suspended nanosheets, the first gate structure separated from the second gate structure by the dielectric wall.

Example 28 is an integrated circuit that includes a first semiconductor device having a first semiconductor region extending in a first direction from a first source or drain region, and a first gate structure extending in a second direction over the first semiconductor region, and a second semiconductor device having a second semiconductor region extending in the first direction from a second source or drain region, and a second gate structure extending in the second direction over the second semiconductor region. The second source or drain region is adjacent to the first source or drain region along the second direction. The integrated circuit also includes a dielectric layer beneath the first source or drain region and the second source or drain region, a first conductive contact extending through an entire thickness of the dielectric layer and contacting an underside of the first source or drain region, a second conductive contact extending through the entire thickness of the dielectric layer and contacting an underside of the second source or drain region, and a dielectric wall extending in the first direction between the first source or drain region and the second source or drain region. The dielectric wall further extends in a third direction between the first conductive contact and the second conductive contact.

Example 29 includes the integrated circuit of Example 28, wherein the dielectric wall directly contacts both the first conductive contact and the second conductive contact.

Example 30 includes the integrated circuit of Example 28 or 29, further comprising a first conductive layer on the first conductive contact and a second conductive layer on the second conductive contact, wherein the dielectric wall extends in the third direction directly between the first conductive layer and the second conductive layer.

Example 31 includes the integrated circuit of any one of Examples 28-30, further comprising a first dielectric fill on a topside of the first source or drain region and a second dielectric fill on a topside of the second source or drain region, wherein the dielectric wall extends in the third direction directly between the first dielectric fill and the second dielectric fill.

Example 32 includes the integrated circuit of any one of Examples 28-31, wherein the dielectric layer comprises silicon and oxygen.

Example 33 includes the integrated circuit of any one of Examples 28-32, wherein the dielectric wall comprises silicon and nitrogen.

Example 34 includes the integrated circuit of any one of Examples 28-33, wherein the dielectric wall has a width in the second direction between about 5 nm and about 30 nm.

Example 35 includes the integrated circuit of any one of Examples 28-34, wherein the first semiconductor region comprises a plurality of first semiconductor nanosheets and the second semiconductor region comprises a plurality of second semiconductor nanosheets.

Example 36 includes the integrated circuit of Example 35, wherein the plurality of first semiconductor nanosheets and the plurality of second semiconductor nanosheets comprise germanium, silicon, or a combination thereof.

Example 37 includes the integrated circuit of any one of Examples 28-36, wherein the second direction is substantially perpendicular to the first direction and wherein the third direction is substantially perpendicular to both the first and second directions.

Example 38 is a printed circuit board comprising the integrated circuit of any one of Examples 28-37.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a first semiconductor device having a first semiconductor region extending in a first direction from a first source or drain region, and a first gate structure extending in a second direction over the first semiconductor region;
a second semiconductor device having a second semiconductor region extending in the first direction from a second source or drain region, and a second gate structure extending in the second direction over the second semiconductor region, the second source or drain region being adjacent to the first source or drain region along the second direction;
a first conductive contact on an underside of the first source or drain region and a second conductive contact on an underside of the second source or drain region; and
a dielectric wall extending in the first direction between and contacting both the first semiconductor region and the second semiconductor region, and extending between both the first source or drain region and the second source or drain region, wherein the dielectric wall further extends in a third direction along at least an entire thickness of the first conductive contact and the second conductive contact.

2. The integrated circuit of claim 1, wherein the dielectric wall directly contacts a sidewall of the first conductive contact and a sidewall of the second conductive contact.

3. The integrated circuit of claim 1, further comprising a first conductive layer on the first conductive contact and a second conductive layer on the second conductive contact, wherein the dielectric wall extends in the third direction between the first conductive layer and the second conductive layer.

4. The integrated circuit of claim 1, further comprising a first dielectric fill on a topside of the first source or drain region and a second dielectric fill on a topside of the second source or drain region, wherein the dielectric wall extends in the third direction between the first dielectric fill and the second dielectric fill.

5. The integrated circuit of claim 1, further comprising a dielectric layer adjacent to the first conductive contact and the second conductive contact.

6. The integrated circuit of claim 1, wherein the dielectric wall has a width in the second direction between about 5 nm and about 30 nm.

7. The integrated circuit of claim 1, wherein the second direction is substantially perpendicular to the first direction and wherein the third direction is substantially perpendicular to both the first and second directions.

8. A printed circuit board comprising the integrated circuit of claim 1.

9. An electronic device, comprising:
a chip package comprising one or more dies, at least one of the one or more dies comprising
a first semiconductor device having a first semiconductor region extending in a first direction between a first source or drain region and a second source or drain region, and a first gate structure extending in a second direction over the first semiconductor region;
a second semiconductor device having a second semiconductor region extending in the first direction between a third source or drain region and a fourth source or drain region, and a second gate structure extending in the second direction over the second semiconductor region;
a first conductive contact on an underside of the first source or drain region and a second conductive contact on an underside of the third source or drain region; and
a dielectric wall extending in the first direction between and contacting both the first semiconductor region and the second semiconductor region, extending in the first direction between the first source or drain region and the third source or drain region, and extending in the first direction between the second source or drain region and the fourth source or drain region, wherein the dielectric wall further extends in a third direction along at least an entire thickness of the first conductive contact and the second conductive contact.

10. The electronic device of claim 9, wherein the dielectric wall directly separates the first conductive contact from the second conductive contact.

11. The electronic device of claim 9, further comprising a first conductive layer on the first conductive contact and a second conductive layer on the second conductive contact, wherein the dielectric wall extends in the third direction directly between the first conductive layer and the second conductive layer.

12. The electronic device of claim 9, further comprising a first dielectric fill on a topside of the first source or drain region and a second dielectric fill on a topside of the third source or drain region, wherein the dielectric wall extends in the third direction directly between the first dielectric fill and the second dielectric fill.

13. The electronic device of claim 9, wherein the first semiconductor region comprises a plurality of first semiconductor nanosheets and the second semiconductor region comprises a plurality of second semiconductor nanosheets.

14. The electronic device of claim 9, further comprising a printed circuit board, wherein the chip package is coupled to the printed circuit board.

15. An integrated circuit comprising:
a first semiconductor device having a first semiconductor region extending in a first direction from a first source or drain region, and a first gate structure extending in a second direction over the first semiconductor region;
a second semiconductor device having a second semiconductor region extending in the first direction from a second source or drain region, and a second gate structure extending in the second direction over the second semiconductor region, the second source or drain region being adjacent to the first source or drain region along the second direction;
a dielectric layer beneath the first source or drain region and the second source or drain region;
a first conductive contact extending through an entire thickness of the dielectric layer and contacting an underside of the first source or drain region, and a second conductive contact extending through the entire thickness of the dielectric layer and contacting an underside of the second source or drain region; and
a dielectric wall extending in the first direction between the first source or drain region and the second source or drain region, wherein the dielectric wall further extends in a third direction between the first conductive contact and the second conductive contact.

16. The integrated circuit of claim 15, further comprising a first conductive layer on the first conductive contact and a second conductive layer on the second conductive contact, wherein the dielectric wall extends in the third direction directly between the first conductive layer and the second conductive layer.

17. The integrated circuit of claim 15, further comprising a first dielectric fill on a topside of the first source or drain region and a second dielectric fill on a topside of the second source or drain region, wherein the dielectric wall extends in the third direction directly between the first dielectric fill and the second dielectric fill.

18. The integrated circuit of claim 15, wherein the dielectric wall has a width in the second direction between about 5 nm and about 30 nm.

19. The integrated circuit of claim 15, wherein the second direction is substantially perpendicular to the first direction and wherein the third direction is substantially perpendicular to both the first and second directions.

20. A printed circuit board comprising the integrated circuit of claim 15.
